(19) United States
(12) Patent Application Publication
(10) Pub. No.: US 2025/0070530 A1
(43) Pub. Date: Feb. 27, 2025

(54) LIGHT EMITTING MODULE

(71) Applicants: Hyundai Motor Company, Seoul (KR); Kia Corporation, Seoul (KR); Partron Co., Ltd., Hwaseong-si (KR)

(72) Inventors: Seon-Yong An, Chuncheon-si (KR); Kyoung-Chun Kweon, Hwaseong-si (KR); Kwang-Rae Cho, Hwaseong-si (KR); Young-Sik Lee, Osan-si (KR)

(21) Appl. No.: 18/524,699

(22) Filed: Nov. 30, 2023

(30) Foreign Application Priority Data
Aug. 22, 2023 (KR) 10-2023-0109964

(51) Int. Cl. H01S 5/024; H01S 5/02253; H01S 5/042

(52) U.S. Cl. CPC H01S 5/02461; H01S 5/02253; H01S 5/04256; H01S 5/183

(57) ABSTRACT

An embodiment light emitting module includes a housing part including a bottom portion and a side portion that is upright upward from an outer perimeter portion of the bottom portion, an electrode part coupled by being inserted into an opening in the bottom portion, and a light emitting part mounted on the electrode part.

### CROSS-REFERENCE TO RELATED APPLICATIONS

This application claims the benefit of Korean Patent Application No. 10-2023-0109964, filed on Aug. 22, 2023, which application is hereby incorporated herein by reference.

### TECHNICAL FIELD

The present disclosure relates to a light emitting module.

### BACKGROUND

With the development of technologies such as an autonomous driving technology or a vehicle navigation, a target detection and tracking system for acquiring accurate information on a target has been developed and used.

Therefore, in order to secure accurate position information on the target, a light detection and ranging (LiDAR) or a time of flight (TOF) technology for measuring a distance at which light is irradiated to the target is used, and embodiments of the present disclosure relate to a light emitting module applied to such a system.

However, in the case of using a general printed circuit board (PCB) in a conventional vertical cavity surface emitting laser (VCSEL) package as a light emitting module, there is a limit in that high heat of the VCSEL may not be smoothly discharged.

Matters described above in the background section are intended to help understanding of the background of embodiments of the disclosure and may include matters not related to the related art already known to those skilled in the art to which this technology pertains.

### SUMMARY

The present disclosure relates to a light emitting module. Particular embodiments relate to a light emitting module for a target detection and tracking system.

Embodiments of the present disclosure can solve problems in the art and are directed to providing a light emitting module capable of effectively discharging heat of a VCSEL compared to the conventional one by applying a quad flat no-lead (QFN) package.

A light emitting module according to one embodiment of the present disclosure includes a housing part including a bottom portion and a side portion that is upright upward from an outer perimeter portion of the bottom portion and formed with a mounting space in which a light emitting part is mounted, an electrode part coupled by being inserted into an opening formed in the bottom portion, and the light emitting part mounted on the electrode part.

In particular, a lower surface of the electrode part may be exposed to the outside.

In addition, a plurality of electrode parts may be formed and coupled by being inserted into a plurality of openings formed in the bottom portion, respectively.

Furthermore, the electrode part may include a first electrode body, a second electrode body, and a third electrode body, the light emitting part may be coupled on the second electrode body disposed at the center, and the light emitting part may be connected to the first electrode body and the second electrode body by a wire.

Meanwhile, the light emitting module may further include a lens part coupled to the side portion and disposed above the light emitting part.

In addition, a side portion discharge groove, which is recessed from an inner surface and open upward, may be formed at one side of the side portion.

In addition, the housing part may further include a stepped portion protruding inward from the inner surface of the side portion to form a step difference with an upper portion of the side portion.

Here, the lens part may be bonded to an upper surface of the stepped portion and the inner surface of the side portion.

In addition, an adhesive injection groove, which is open laterally, may be formed in the upper portion of the side portion.

Furthermore, the inner surface of the side portion may be inclined inward as it goes down.

Meanwhile, a stepped portion discharge hole, which communicates with the side portion discharge groove and passes through upper and lower surfaces of the stepped portion, may be formed in the stepped portion.

Alternatively, a stepped portion discharge groove, which communicates with the side portion discharge groove and the mounting space, may be formed in an upper surface of the stepped portion.

The light emitting module according to embodiments of the present disclosure can increase the transmission efficiency of the signal using the electrode body made of metal instead of using the conventional PCB.

In addition, since the light emitting part is positioned on the electrode body and the heat generated by the operation of the light emitting part is discharged through the electrode body positioned on the lower portion thereof, the heat generated by the operation of the light emitting part may be discharged even without using the separate heat dissipation plate.

Furthermore, since the adhesive is applied to the side surface as well as the lower surface of the lens part, it is possible to prevent the lens array sheet from being separated by a difference in physical properties between the lens body and the lens array sheet.

In addition, since the adhesive may be injected by using the adhesive injection groove so that the adhesive may be applied to the side surface of the lens part, it is possible to easily and simply perform the injection operation of the adhesive.

Furthermore, the heat generated inside the light emitting module may be smoothly discharged to the outside through the discharge groove formed in the housing. Therefore, it is possible to prevent problems such as damage to the light emitting module or deterioration in operational accuracy due to the heat generated by the operation of the light emitting module.

### BRIEF DESCRIPTION OF THE DRAWINGS

FIG. 1 is a perspective view illustrating a light emitting module according to embodiments of the present disclosure.

FIG. 2 is a rear perspective view illustrating the light emitting module according to embodiments of the present disclosure.

FIG. 3 is an exploded perspective view illustrating the light emitting module according to embodiments of the present disclosure.

FIG. 4 is a rear exploded perspective view illustrating the light emitting module according to embodiments of the present disclosure.

FIG. 5 is a side cross-sectional view illustrating the light emitting module according to embodiments of the present disclosure.

FIG. 6 is a partial perspective view illustrating a light emitting module according to another embodiment of the present disclosure.

### DETAILED DESCRIPTION OF ILLUSTRATIVE EMBODIMENTS

For a full understanding of embodiments of the present disclosure, operational advantages of embodiments of the present disclosure, and objects to be achieved by practicing embodiments of the present disclosure, reference should be made to the accompanying drawings, which illustrate preferred embodiments of the present disclosure, and contents described in the accompanying drawings.

In describing the preferred embodiments of the present disclosure, a description of known techniques or repetitive descriptions that may unnecessarily obscure the gist of the embodiments of the present disclosure will be reduced or omitted.

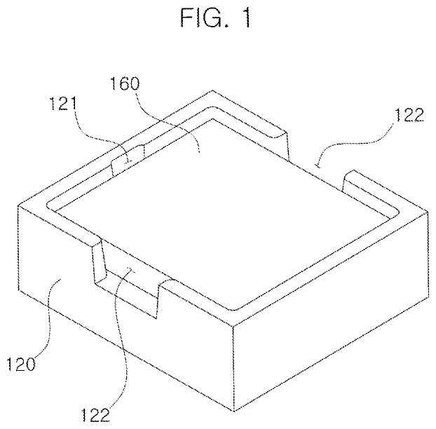

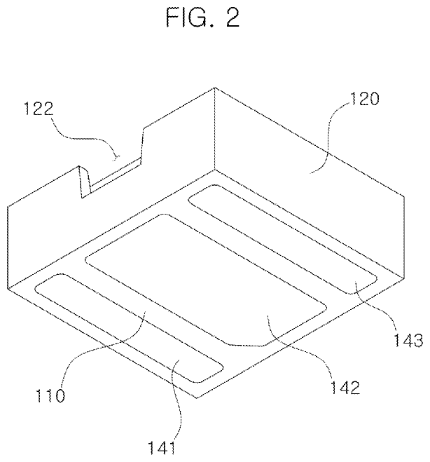

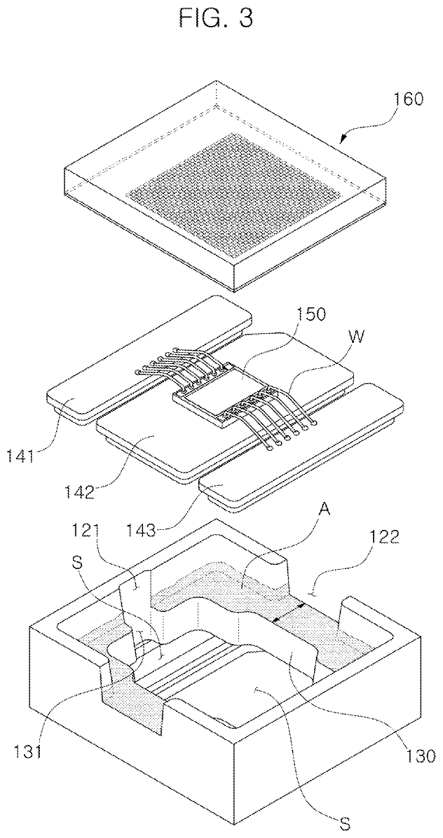

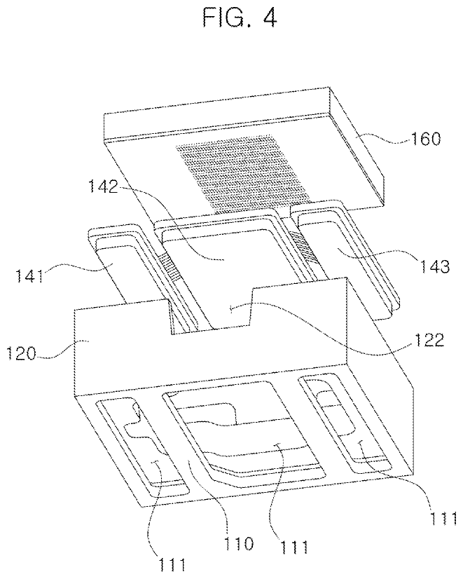

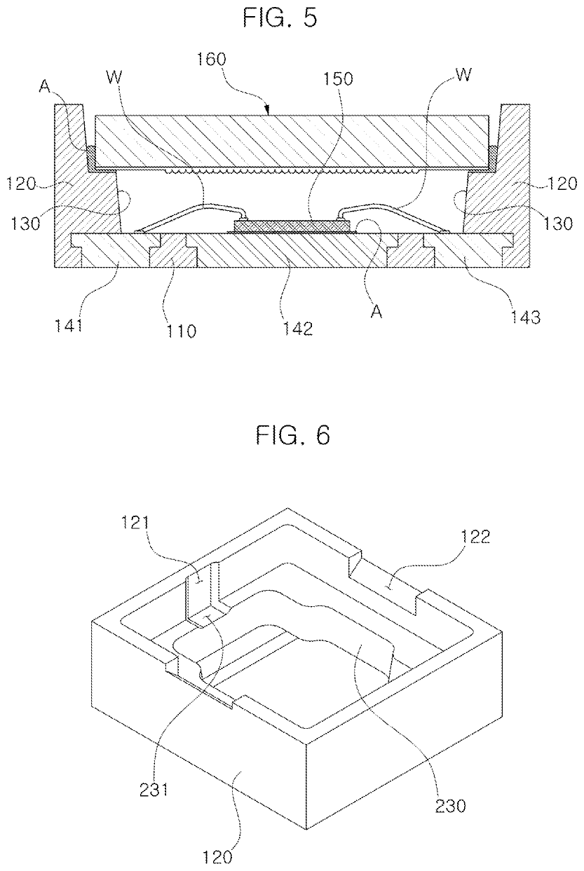

FIG. 1 is a perspective view illustrating a light emitting module according to embodiments of the present disclosure, and FIG. 2 is a rear perspective view illustrating the light emitting module according to embodiments of the present disclosure. In addition, FIG. 3 is an exploded perspective view illustrating the light emitting module according to embodiments of the present disclosure, and FIG. 4 is a rear exploded perspective view illustrating the light emitting module according to embodiments of the present disclosure. In addition, FIG. 5 is a side cross-sectional view illustrating the light emitting module according to embodiments of the present disclosure.

Hereinafter, a light emitting module according to one embodiment of the present disclosure will be described with reference to FIGS. 1 to 5.

Embodiments of the present disclosure provide a light emitting module for a target detection and tracking system such as an autonomous driving technology and are intended to allow high heat from a light emitting device such as a vertical cavity surface emitting laser (VCSEL) to be effectively discharged compared to the conventional one, and in order to achieve this, a quad flat no-lead (QFN) package structure is applied.

To this end, the light emitting module according to embodiments of the present disclosure includes a housing part, an electrode part coupled to the housing part, a light emitting part bonded to the electrode part, and a lens part disposed above the light emitting part and coupled to the housing part.

The housing part includes a bottom portion 110, a side portion 120, and a stepped portion 130, functions to electrically connect the light emitting part, and functions as a packaging that supports the lens part and protects the light emitting part.

The bottom portion 110 forms a lower base, an opening 111 that is vertically open is formed, and the electrode part to be described below is coupled to the opening 111.

The side portion 120 may have a shape that is upright upward along an outer perimeter from an outer perimeter portion of the bottom portion 110 and may be coupled to or integrally formed with the bottom portion 110.

The stepped portion 130 protrudes inward from an inner surface of the side portion 120 to form a step difference with an upper portion of the side portion 120.

In other words, the stepped portion 130 protrudes from a lower portion of the side portion 120 and has a lower surface formed in contact with the bottom portion 110 so that the lens part 160 is coupled by being mounted on an upper surface of the stepped portion 130.

The lens part 160 may include a lens body and a lens array sheet formed on one surface of the lens body at a light emitting part 150 side and coupled to the housing part and disposed above the light emitting part 150.

The lens part 160 according to embodiments of the present disclosure may be coupled by being bonded to the housing part and coupled by forming an adhesive portion A between the lens part 160 and the housing part using an adhesive.

As illustrated in FIG. 5, the adhesive portion A may be formed between the upper surface and the side portion 120 of the stepped portion 130 and the lens part 160, and in order to inject the adhesive, an adhesive injection groove 122 may be formed at one side of the side portion 120.

In other words, the adhesive injection groove 122, which is open from an upper end surface of the side portion 120 to a height of an upper end of the stepped portion 130, may be formed, and a plurality of the adhesive injection grooves 122 may be formed.

In addition, in order to facilitate the injection of the adhesive, it is preferable that the inner surface of the side portion 120 is inclined inward as it goes down.

As described above, when the lens part 160 is bonded to the housing part, a module mounting space S is sealed, and in embodiments of the present disclosure, by forming a side portion discharge groove 121 at one side of the side portion 120, heat from the mounting space S may be discharged through the side portion discharge groove 121.

In other words, it is possible to prevent problems such as damage or lifting of the lens part 160 due to an increase in a temperature of air positioned in the mounting space S by a heat treatment process, etc.

As illustrated, the side portion discharge groove 121 may have a shape that is partially recessed from the inner surface of the side portion 120 and open upward.

Furthermore, a stepped portion discharge hole 131 communicating with the side portion discharge groove 121 may be formed in the stepped portion 130.

In other words, since the upper surface of the stepped portion 130 is bonded to the lens part 160, in order to discharge the heat from the mounting space S, a stepped portion discharge groove in which at least a portion of the upper surface of the stepped portion 130 is open should be formed.

An embodiment in which a stepped portion discharge groove 231 is formed in only a portion of the upper surface of the stepped portion 230 is illustrated in FIG. 6.

On the other hand, in the embodiment of FIG. 3, a stepped portion discharge hole 131 may be formed to pass through the upper and lower surfaces of the stepped portion 130 for better discharge.

Next, in embodiments of the present disclosure, an electrode part made of a conductive material such as metal may be coupled by being inserted into the opening 111 formed in the bottom portion 110, and furthermore, a lower surface of the electrode part may be exposed to the outside downward.

In addition, the light emitting part 150 such as a VCSEL may be mounted on the upper surface of the electrode part and coupled by the adhesive portion A.

According to embodiments of the present disclosure, the heat generated by the light emitting part 150 may be discharged to the outside through the electrode part through the QFN package structure.

A plurality of electrode parts according to embodiments of the present disclosure may be formed, and a plurality of openings 111 for each electrode part may be formed in the bottom portion 110.

As in the example, the electrode part may include a first electrode body 141, a second electrode body 142, and a third electrode body 143, and the number, size, and arrangement thereof may be different from those in the example.

A portion of the electrode part in the example may function as an electrode electrically and physically connected to the light emitting part 150 to transmit signals necessary for the operation of the light emitting part 150, and the other one may function as a heat dissipation plate for discharging the heat generated by the operation of the light emitting part 150 as well as an installation portion on which the light emitting part 150 is positioned.

The light emitting part 150 may be coupled on the second electrode body 142 disposed at the center, and the light emitting part 150, the first electrode body 141, and the second electrode body 142 may be connected by a wire W.

As described above, in embodiments of the present disclosure, since plus and minus terminals of the package are connected to the anode and cathode of the VCSEL through the electrode body made of a single metal, it is more advantageous in terms of a resistance component of a circuit and a component (inductance) that interferes with a signal during high-frequency operation (because a width (area) of the circuit connected to the outside is wider without using a via having a narrow cross-section area or the like).

In addition, upon using a general PCB base substrate, a bonding process is required because a housing and a substrate are separately formed, while the QFN type according to embodiments of the present disclosure does not require a housing attach process because it is an integrated type.

In addition, since the electrode is formed in the QFN type and is made of metal, it is possible to effectively dissipate heat.

In other words, upon using the general PCB base substrate, the thermal conductivity of FR4, which is a PCB material, is smaller than 1 mW/mk and is very low compared to metal. The QFN type package is more advantageous for heat dissipation of a VCSEL with a large area and high thermal conductivity because the electrode body is made of a metal (copper alloy) whose size is larger than that of the VCSEL (thermal conductivity of copper alloy: 250 to 400 W/mk).

Meanwhile, since the discharge groove/the discharge hole are present, it is possible to prevent damage due to internal/external heat circulation. In other words, when there is no vent hole, the internal air expands due to heat during the heat treatment process and the operation of the light emitting module, and thus a mechanical stress is applied to a glass, resulting in the damage and lifting of the lens part, but the vent hole causes the heat generated therein and the expanded air to be discharged to the outside, which is conducive to the operation of the VCSEL and the structural stability of the package.

In addition, when the adhesive is applied to the side surface of the lens part by injecting an epoxy through the adhesive injection groove, the lens array sheet and the lens body are fixed together on the side surface of the lens, and thus it is more advantageous to prevent the lens array sheet from being separated due to a difference in physical characteristics such as a coefficient of thermal expansion (CTE).

Although embodiments of the present disclosure have been described above with reference to the exemplary drawings, the embodiments of the present disclosure are not limited to the described embodiments, and it is apparent to those skilled in the art that various modifications and changes can be made without departing from the spirit and scope of the embodiments of the present disclosure. Therefore, these modified examples or changed examples should be included in the claims of the present disclosure, and the scope of the embodiments of the present disclosure should be construed based on the appended claims.

What is claimed is:

1. A light emitting module comprising:
a housing part comprising a bottom portion and a side portion that is upright upward from an outer perimeter portion of the bottom portion;
an electrode part coupled by being inserted into an opening in the bottom portion; and
a light emitting part mounted on the electrode part.

2. The light emitting module of claim 1, wherein a lower surface of the electrode part is exposed to an outside.

3. The light emitting module of claim 2, wherein a plurality of electrode parts are coupled by being inserted into a plurality of openings in the bottom portion, respectively.

4. The light emitting module of claim 1, wherein the electrode part comprises a first electrode body, a second electrode body, and a third electrode body.

5. The light emitting module of claim 4, wherein the light emitting part is coupled on the second electrode body disposed at a center and is connected to the first electrode body and the second electrode body by wires.

6. A light emitting module comprising:
a housing part comprising a bottom portion and a side portion that is upright upward from an outer perimeter portion of the bottom portion;
an electrode part coupled by being inserted into an opening in the bottom portion;
a light emitting part mounted on the electrode part; and
a lens part coupled to the side portion and disposed above the light emitting part.

7. The light emitting module of claim 6, wherein a side portion discharge groove is disposed at one side of the side portion, the side portion discharge groove being recessed from an inner surface of the side portion and open upward.

8. The light emitting module of claim 7, wherein the housing part further comprises a stepped portion protruding inward from the inner surface of the side portion to define a step difference with an upper portion of the side portion.

9. The light emitting module of claim 8, wherein the lens part is bonded to an upper surface of the stepped portion and the inner surface of the side portion.

10. The light emitting module of claim 9, wherein an adhesive injection groove is disposed in the upper portion of the side portion, the adhesive injection groove being open laterally.

11. The light emitting module of claim 10, wherein the inner surface of the side portion is inclined inward from the upper portion of the side portion to a lower portion of the side portion.

12. The light emitting module of claim 8, wherein a stepped portion discharge hole is disposed in the stepped portion, the stepped portion discharge hole being in communication with the side portion discharge groove and passing through upper and lower surfaces of the stepped portion.

13. The light emitting module of claim 8, wherein a stepped portion discharge groove is disposed in an upper surface of the stepped portion, the stepped portion discharge groove being in communication with the side portion discharge groove and a mounting space in the housing part.

14. A light emitting module comprising:
a housing part comprising a bottom portion, a side portion, and a stepped portion protruding inward from an inner surface of the side portion and having a step difference with an upper portion of the side portion;
an electrode part coupled to an opening in the bottom portion of the housing part;
a light emitting part bonded to the electrode part; and
a lens part disposed above the light emitting part and coupled to the housing part.

15. The light emitting module according to claim 14, wherein the lens part is mounted on an upper surface of the stepped portion.

16. The light emitting module according to claim 14, wherein the lens part comprises a lens body and a lens array sheet disposed on a surface of the lens body, and wherein an adhesive is disposed between the lens part and the housing part.

17. The light emitting module according to claim 16, wherein an adhesive injection groove is disposed at a side of the side portion, the adhesive injection groove being configured to allow the adhesive to be injected.

18. The light emitting module according to claim 14, wherein the electrode part comprises a first electrode body, a second electrode body, and a third electrode body, the second electrode body being disposed between the first electrode body and the second electrode body.

19. The light emitting module according to claim 18, wherein the light emitting part is coupled on the second electrode body, and wherein the light emitting part, the first electrode body, and the second electrode body are connected by a wire.

20. The light emitting module of claim 14, wherein the inner surface of the side portion is inclined inward from the upper portion of the side portion to a lower portion of the side portion.
